(19) United States
(12) Patent Application Publication
(10) Pub. No.: US 2013/0020663 A1
(43) Pub. Date: Jan. 24, 2013

(54) SOLID-STATE IMAGING DEVICE AND PRODUCTION METHOD THEREFOR, AND ELECTRONIC APPARATUS

(71) Applicant: Kaori Takimoto, Kanagawa (JP)

(72) Inventor: Kaori Takimoto, Kanagawa (JP)

(73) Assignee: SONY CORPORATION, Tokyo (JP)

(21) Appl. No.: 13/547,655

(22) Filed: Jul. 12, 2012

(30) Foreign Application Priority Data
Jul. 19, 2011 (JP) 2011-158051

(51) Int. Cl. H01L 31/0224; H01L 31/18

(52) U.S. Cl. 257/431; 438/98; 257/E31.126; 257/E31.001

(57) ABSTRACT

A solid-state imaging device includes a semiconductor substrate and a photoelectric conversion layer above the semiconductor substrate. The photoelectric conversion layer includes a lower electrode having a side surface insulated with an insulating film, a photoelectric conversion film on the lower electrode, and an upper electrode. The upper electrode and the lower electrode sandwich the photoelectric conversion film. An upper surface of the lower electrode is lower than an upper surface of the insulating film.

### BACKGROUND

The present disclosure relates to solid-state imaging devices, production methods therefor, and electronic apparatuses. In particular, it relates to a solid-state imaging device, a production method therefor, and an electronic apparatus with which deterioration of photoelectric conversion characteristics can be prevented.

Solid-state imaging devices such as complementary metal oxide semiconductor (CMOS) image sensors and charge coupled devices (CCDs) are widely used in digital still cameras and digital video cameras, etc. In recent years, the pixel size of solid-state imaging devices has been increasingly reduced and thus the number of photons coming into a unit pixel has decreased. As a result, the sensitivity and the signal-to-noise (S/N) ratio of solid-state imaging devices have shown a decreasing tendency.

In typical solid-state imaging devices, a pixel array in which red, green, and blue pixels are aligned next to one another on a flat surface, such as a Bayer array that uses primary color filters, has been used. In a red pixel of such a solid-state imaging device that uses color filters, green light and blue light do not pass through the color filter and thus are not used in photoelectric conversion, resulting in loss of sensitivity. Furthermore, while color signals are generated by pixel interpolation, false colors occur.

Such loss of sensitivity and occurrence of false colors have been addressed by employing a pixel structure constituted by three photoelectric conversion layers stacked in a vertical direction to form one pixel. A solid-imaging device employing this structure can obtain photoelectric conversion signals of three colors from one pixel.

For example, Japanese Unexamined Patent Application Publication No. 2003-332551 (Patent Document 1) discloses a sensor in which a photoelectric conversion unit configured to detect green light and generate a signal charge in response thereto is provided above a silicon substrate and two photodiodes configured to detect blue and red light are stacked inside the silicon substrate.

Also suggested is a back-illuminated-type solid-state imaging device, i.e., an imaging device in which a circuit-forming surface is disposed on the opposite side of the light-receiving surface, having a structure in which one photoelectric conversion film of one color is provided above a silicon substrate and two photoelectric conversion units of other two colors are provided in the silicon substrate.

In particular, Japanese Unexamined Patent Application Publication No. 2011-29337 (Patent Document 2) discloses a back-illuminated device in which an organic photoelectric conversion layer is formed. Since no circuits or wires are formed between an inorganic photoelectric conversion unit and the organic photoelectric conversion unit, the distance between the inorganic photoelectric conversion unit and the organic photoelectric conversion unit in the same pixel can be decreased. As a result, the F-number dependence of each color can be suppressed, and variation of sensitivity among different colors can be suppressed.

Basically, as described in Patent Document 1, a photoelectric conversion unit includes a first electrode film, a photoelectric conversion film constituted by stacking organic materials, and a multilayered second electrode film. Japanese Unexamined Patent Application Publication Nos. 2007-81137 (Patent Document 3) and 2010-62380 (Patent Document 4) disclose such a device structure.

For example, Patent Document 4 discloses a structure of a photoelectric conversion unit that includes a lower electrode formed on an interlayer insulating film, a photoelectric conversion layer that covers the lower electrode and has an inverted-letter-U shaped cross-section opening downward, and an upper electrode that covers the photoelectric conversion layer to seal the photoelectric conversion layer from outside. According to this structure, the photoelectric conversion layer is constituted by side surface portions that cover side surfaces of the lower electrode and an upper surface portion that covers the upper surface of the lower electrode, and protrudes upward.

### SUMMARY

As described in Patent Document 4, an organic photoelectric conversion film preferably has high orientation controllability. However, in the structure disclosed in Patent Document 4, the orientation of the organic photoelectric conversion film at the side wall portions of the lower electrode is different from that at the upper surface portion of the lower electrode, which may result in deterioration of photoelectric conversion characteristics.

According to the present disclosure, deterioration of photoelectric conversion characteristics is avoided.

According to an embodiment of the disclosure, there is provided a solid-state imaging device that includes a semiconductor substrate and a photoelectric conversion layer above the semiconductor substrate. The photoelectric conversion layer includes a lower electrode having a side surface insulated with an insulating film, a photoelectric conversion film on the lower electrode, and an upper electrode, the upper electrode and the lower electrode sandwiching the photoelectric conversion film. A upper surface of the lower electrode is lower than an upper surface of the insulating film.

According to another embodiment of the disclosure, there is provided a method for producing a solid-state imaging device that includes a semiconductor substrate and a photoelectric conversion layer above the semiconductor substrate. The method includes forming an interlayer insulating film on the semiconductor substrate; forming a lower electrode on the interlayer insulating film; forming an insulating film on the interlayer insulating film and the lower electrode and planarizing the insulating film so as to expose the lower electrode; forming a photoelectric conversion film on the lower electrode; and forming an upper electrode so as to sandwich the photoelectric conversion film between the upper electrode and the lower electrode. In this method, in planarizing the insulating film, an upper surface of the lower electrode is formed to be lower than an upper surface of the insulating film.

According to yet another embodiment of the disclosure, there is provided a method for producing a solid-state imaging device that includes a semiconductor substrate and a photoelectric conversion layer above the semiconductor substrate. The method includes forming an interlayer insulating film on the semiconductor substrate; forming an insulating film on the interlayer insulating film, the insulating film having an opening in a region where a lower electrode is to be formed; forming an electrode film, which is to form the lower electrode, on the interlayer insulating film and the insulating film and planarizing the electrode film so as to expose the insulating film and to thereby form the lower electrode; forming a photoelectric conversion film on the lower electrode; and forming an upper electrode so that the photoelectric conversion film is sandwiched between the lower electrode and the upper electrode. In the method, in planarizing the insulating film, an upper surface of the lower electrode is formed to be lower than an upper surface of the insulating film.

According to still another embodiment of the disclosure, there is provided an electronic apparatus that includes a solid-state imaging device. The solid-state imaging device includes a semiconductor substrate and a photoelectric conversion layer above the semiconductor substrate. The photoelectric conversion layer includes a lower electrode having a side surface insulated with an insulating film; a photoelectric conversion film on the lower electrode; and an upper electrode, the upper electrode and the lower electrode sandwiching the photoelectric conversion film. An upper surface of the lower electrode is lower than an upper surface of the insulating film.

According to these embodiments, deterioration of the photoelectric conversion characteristics can be avoided.

### BRIEF DESCRIPTION OF THE DRAWINGS

FIG. 1 is a cross-sectional view showing an example of a structure of a solid-state imaging device according to one embodiment;

FIG. 2 is a cross-sectional view illustrating a first step of a first method for producing a solid-state imaging device;

FIG. 3 is a cross-sectional view illustrating a second step;

FIG. 4 is a cross-sectional view illustrating a third step;

FIG. 5 is a cross-sectional view illustrating a fourth step;

FIG. 6 is a cross-sectional view illustrating a fifth step;

FIG. 7 is a cross-sectional view illustrating a sixth step;

FIG. 8 is a cross-sectional view illustrating a seventh step;

FIG. 9 is a cross-sectional view illustrating an eighth step;

FIG. 10 is a cross-sectional view illustrating a ninth step;

FIG. 11 is a diagram showing another example of a process for planarizing an insulating film;

FIGS. 12A and 12B illustrate a process conducted when a lower electrode has a protruding structure;

FIG. 13 is a cross-sectional view illustrating a tenth step in a second method for producing a solid-state imaging device;

FIG. 14 is a cross-sectional view illustrating an eleventh step;

FIG. 15 is a cross-sectional view illustrating a twelfth step;

FIG. 16 is a cross-sectional view illustrating a thirteenth step;

FIGS. 17A to 17C are diagrams used in describing erosion;

FIGS. 18A to 18C are diagrams used in describing dishing;

FIG. 19 is a block diagram showing an example configuration of an imaging system mounted in an electronic apparatus.

### DETAILED DESCRIPTION OF EMBODIMENTS

Specific embodiments to which the technique of the present disclosure is applied will now be described in detail with reference to drawings.

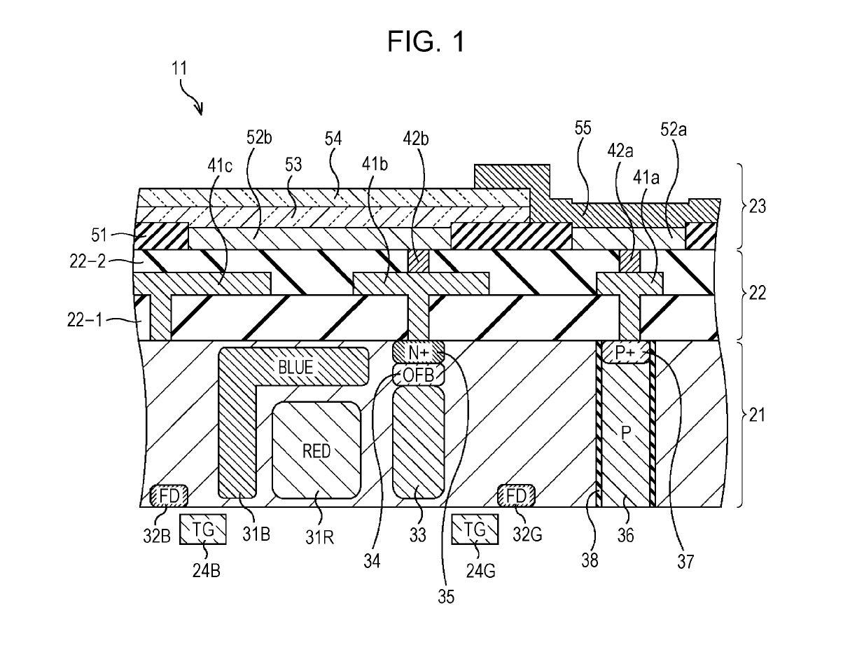

FIG. 1 is a cross-sectional view showing an example of a structure of a first embodiment of a solid-state imaging device.

A cross-section of one pixel of a solid-state imaging device 11 and its nearby portion are shown in FIG. 1. The solid-state imaging device 11 includes a semiconductor element substrate 21, an interlayer insulating film 22, and a photoelectric conversion layer 23, stacked in that order from the bottom.

The solid-state imaging device 11 is a back-illuminated CMOS sensor in which light is incident on a back surface (the surface facing upward in FIG. 1) opposite to a front surface of the semiconductor element substrate 21 on which wiring layers are stacked. Transfer transistors 24B and 24G, other transistors not shown in the drawing, and multilayer interconnection layers (not shown) in which a plurality of wiring layers are stacked with interlayer insulating films therebetween are stacked on the front surface side of the semiconductor element substrate 21. Peripheral circuits such as logic circuits (not shown) are formed in a peripheral region of the solid-state imaging device 11, the peripheral region being outside the region in which a pixel array is formed.

Photoelectric conversion units 31B and 31R, floating diffusions 32B and 32G, a charge-storing unit 33, an overflow barrier 34, a contact unit 35, an ion injection plug 36, a contact unit 37, and an insulating film 38 are formed in the semiconductor element substrate 21.

The photoelectric conversion unit 31B is formed near the back surface side of the semiconductor element substrate 21 at a depth that allows the photoelectric conversion unit 31B to efficiently convert blue light into electric signals. The photoelectric conversion unit 31B extends from this region toward the front surface of the semiconductor element substrate 21. Charges generated by photoelectric conversion of blue light using the photoelectric conversion unit 31B are transferred to the floating diffusion 32B via the transfer transistor 24B and read out.

The transfer transistor 24B is positioned to be adjacent to a region where the portion of the photoelectric conversion unit 31B extending to be near the front surface of the semiconductor element substrate 21 lies. The transfer transistor 24B is formed on an insulating film on the front surface of the semiconductor element substrate 21. The floating diffusion 32B is formed to be in contact with the front surface of the semiconductor element substrate 21 and is located at a position spaced from the photoelectric conversion unit 31B with the transfer transistor 24B therebetween.

The photoelectric conversion unit 31R in the semiconductor element substrate 21 is located at a position deeper than where the photoelectric conversion unit 31B is formed. The photoelectric conversion unit 31R is formed in a region at a depth that can efficiently convert red light into electrical signals and converts red light into electric signals. Note that the transfer transistor and the floating diffusion used to read out the charges generated in the photoelectric conversion unit 31R are omitted from the drawing.

The charge-storing unit 33 stores charges generated by converting green light into electric signals using the photoelectric conversion layer 23 as described below. The charge-storing unit 33 is connected to the back surface of the semiconductor element substrate 21 via the overflow barrier 34 and the contact unit 35. The charge-storing unit 33 extends to a region near the front surface of the semiconductor element substrate 21.

The overflow barrier 34 is formed between the charge-storing unit 33 and the contact unit 35. The overflow barrier 34 functions as a barrier when charges generated by the photoelectric conversion layer 23 flow into the charge-storing unit 33. The contact unit 35 is an N+-type region in contact with the back surface of the semiconductor element substrate 21 and is connected to a conductive film 41b formed in the interlayer insulating film 22.

Charges stored in the charge-storing unit 33 are transferred to the floating diffusion 32G via the transfer transistor 24G and read out. The transfer transistor 24G is located to be adjacent to the region in which the charge-storing unit 33 is formed near the front surface of the semiconductor element substrate 21. The transfer transistor 24G is disposed on an insulating film on the front surface of the semiconductor element substrate 21. The floating diffusion 32G is formed to be in contact with the front surface of the semiconductor element substrate 21 and is located at a position spaced from the charge-storing unit 33 with the transfer transistor 24G therebetween.

The ion injection plug 36 is a P-type region penetrating the semiconductor element substrate 21. The potential of a contact metal layer 55 of the photoelectric conversion layer 23 is fixed through a substrate not shown in the drawing via the ion injection plug 36. The contact unit 37 is a P+-type region in contact with the back surface of the semiconductor element substrate 21 and is connected to a conductive film 41a in the interlayer insulating film 22. The insulating film 38 is formed around the ion injection plug 36 and the contact unit 37 so as to insulate the ion injection plug 36 and the contact unit 37 from the semiconductor element substrate 21.

The interlayer insulating film 22 insulates the semiconductor element substrate 21 from the photoelectric conversion layer 23. The interlayer insulating film 22 includes two layers, i.e., an insulating film 22-1 and an insulating film 22-2. Conductive films 41a to 41c and conductive plugs 42a and 42b are formed in the interlayer insulating film 22.

Each of the conductive films 41a to 41c is formed in a contact hole in the insulating film 22-1 and at the interface between the interlayer insulating film 22-1 and the interlayer insulating film 22-2 and functions as a conductive plug and a light-shielding film. In other words, the conductive films 41a to 41c are composed of a light-shielding material and, for example, are formed to expose regions through which light is desirably transmitted while covering the rest of the regions. As a result, light passing through the opening portions shines the photoelectric conversion units 31B and 31R inside the semiconductor element substrate 21. The conductive film 41a is connected to the contact unit 37 and the conductive film 41b is connected to the contact unit 35.

The conductive plugs 42a and 42b are formed in contact holes in the insulating film 22-2. The conductive plug 42a is connected to the conductive film 41a and a lower electrode 52a. The conductive plug 42b is connected to the conductive film 41b and a lower electrode 52b. In other words, the lower electrode 52a is connected to the contact unit 37 via the conductive plug 42a and the conductive film 41a, and the lower electrode 52b is connected to the contact unit 35 via the conductive plug 42b and the conductive film 41b.

The photoelectric conversion layer 23 is formed by stacking an insulating film 51, the lower electrodes 52a and 52b, an organic photoelectric conversion film 53, an upper electrode 54, and the contact metal layer 55.

The insulating film 51 is stacked on the interlayer insulating film 22 to insulate between the lower electrode 52a and the lower electrode 52b.

The lower electrode 52a is an electrode that connects the conductive plug 42a to the contact metal layer 55.

The lower electrode 52b is a transparent electrode connected to a lower surface of the organic photoelectric conversion film 53. A voltage is applied between the lower electrode 52b and the upper electrode 54 so as to transfer charges generated in the organic photoelectric conversion film 53 to the charge-storing unit 33. The lower electrode 52b has an upper surface lower than an upper surface of the insulating film 51 so as to form a recessed structure. The entire upper surface of the lower electrode 52b is in contact with the organic photoelectric conversion film 53 while the side surfaces are completely covered with the insulating film 51.

The organic photoelectric conversion film 53 receives light in a particular wavelength range and converts the light into electric signals. In the example shown in FIG. 1, the organic photoelectric conversion film 53 converts green light into electric signals.

The upper electrode 54 is a transparent electrode connected to the upper surface of the organic photoelectric conversion film 53. A portion of the upper electrode 54 is overlaid by the contact metal layer 55.

The contact metal layer 55 applies to the upper electrode 54 a particular voltage supplied from the front surface side of the semiconductor element substrate 21 via the ion injection plug 36.

The solid-state imaging device 11 having such a configuration has a recessed structure in which the upper surface of the lower electrode 52b is lower than the upper surface of the insulating film 51. Thus, the organic photoelectric conversion film 53 makes contact with only the upper surface of the lower electrode 52b. This facilitates control of orientation of the organic photoelectric conversion film 53 and thus the photoelectric conversion characteristics can be improved.

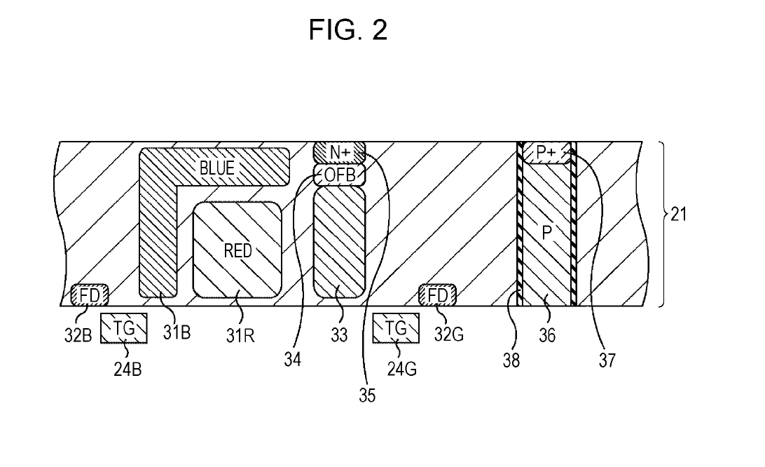

A first method for producing a solid-state imaging device 11 will now be described with reference to FIGS. 2 to 11.

FIG. 2 shows a first step.

In the first step, the photoelectric conversion unit 31B and the photoelectric conversion unit 31R are formed in an overlapping manner inside the semiconductor element substrate 21. The charge-storing unit 33, the overflow barrier 34, and the contact unit 35 are also formed inside the semiconductor element substrate 21 by being stacked on top of the other. The floating diffusion 32B, the floating diffusion 32G, the ion injection plug 36, the contact unit 37, and the insulating film 38 are also formed inside the semiconductor element substrate 21. Then a support substrate is attached to multilayer interconnection layers (not shown) and silicon and a SiO₂ (silicon oxide) film are removed to expose the back surface (surface facing upward in FIG. 2) of a thin silicon layer.

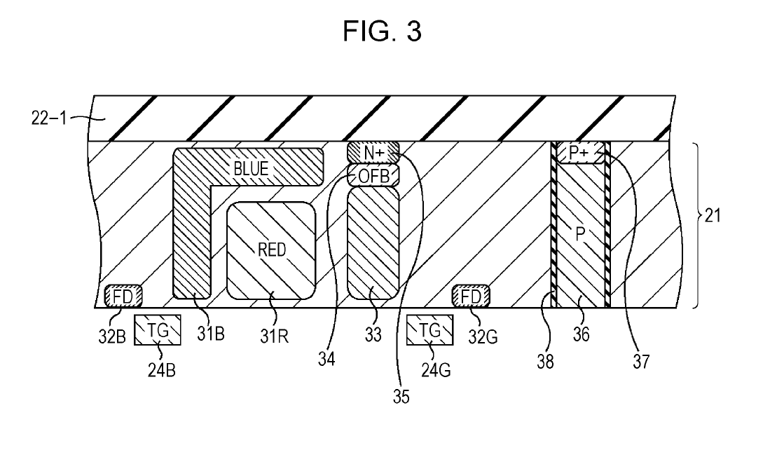

FIG. 3 illustrates a second step.

In the second step, the insulating film 22-1 is formed on the back surface of the semiconductor element substrate 21. The insulating film 22-1 preferably has a small interface state so as to decrease the interface state with respect to the silicon layer constituting the semiconductor element substrate 21 and to suppress generation of dark current from the interface between the silicon layer and the insulating film 22-1. Accordingly, a multilayered film that includes a hafnium oxide (HfO₂) film formed by atomic layer deposition (ALD) and a SiO₂ film formed by plasma-enhanced chemical vapor deposition (CVD) may be used as the insulating film 22-1. The insulating film 22-1 may have other structures of may be formed by any other film-forming technique.

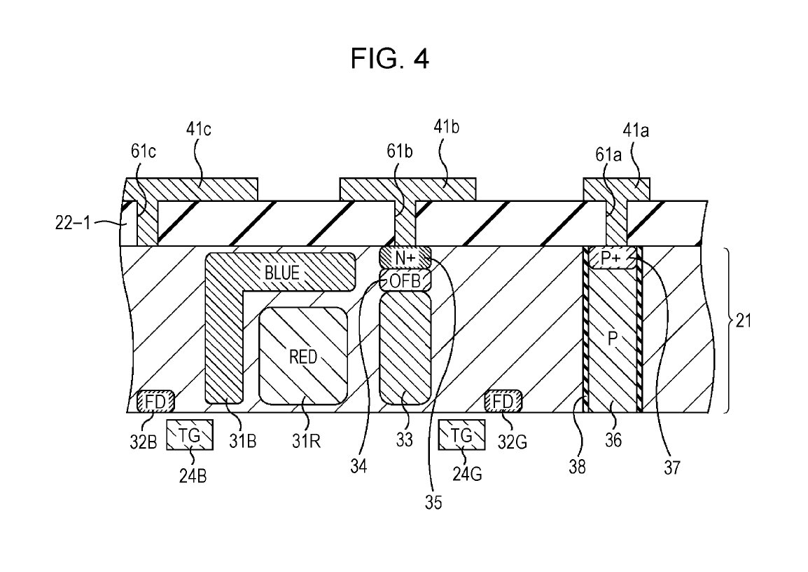

FIG. 4 illustrates a third step.

In the third step, contact holes 61a to 61c are formed in the insulating film 22-1. The contact hole 61a penetrates the insulating film 22-1 and reaches the contact unit 37. The contact hole 61b penetrates the insulating film 22-1 and reaches the contact unit 35. Then a conductive film is formed so as to bury the contact holes 61a to 61c and cover the insulating film 22-1 and partly processed to leave the conductive film only in the portions where light is desirably shielded. As a result, conductive films 41a to 41c are formed. A multilayer film constituted by barrier metals, i.e., titanium (Ti) and titanium nitride (TiN), and tungsten (W) are preferably used in the conductive films 41a to 41c since the conductive films 41a to 41c are to make contact with the semiconductor element substrate 21 and used as light-shielding films. The structure and material of the conductive films 41a to 41c may be any other structure and material.

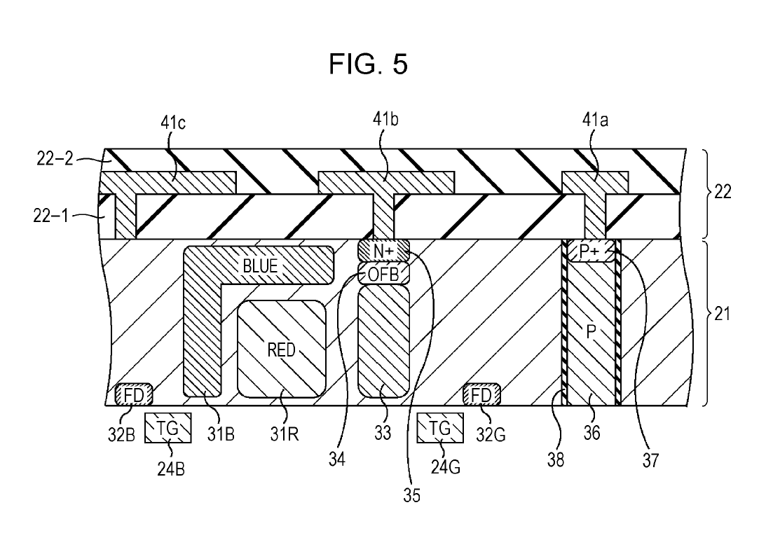

FIG. 5 illustrates a fourth step. In the fourth step, a SiO₂ film is formed by, for example, plasma-enhanced CVD so as to cover the insulating film 22-1 and the conductive films 41a to 41c, and is then planarized by chemical mechanical polishing (CMP) so as to form an insulating film 22-2.

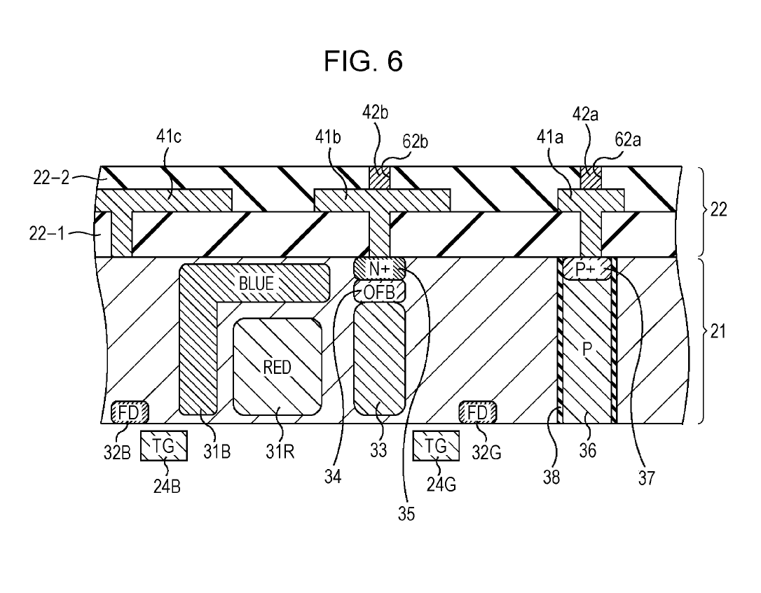

FIG. 6 illustrates a fifth step.

In the fifth step, contact holes 62a and 62b are formed in the insulating film 22-2 and conductive plugs 42a and 42b are formed so as to fill the contact holes 62a and 62b. The conductive plugs 42a and 42b are formed by, for example, depositing a multilayer film of titanium nitride and tungsten and then removing unneeded tungsten and titanium nitride remaining on the insulating film 22-2 by CMP.

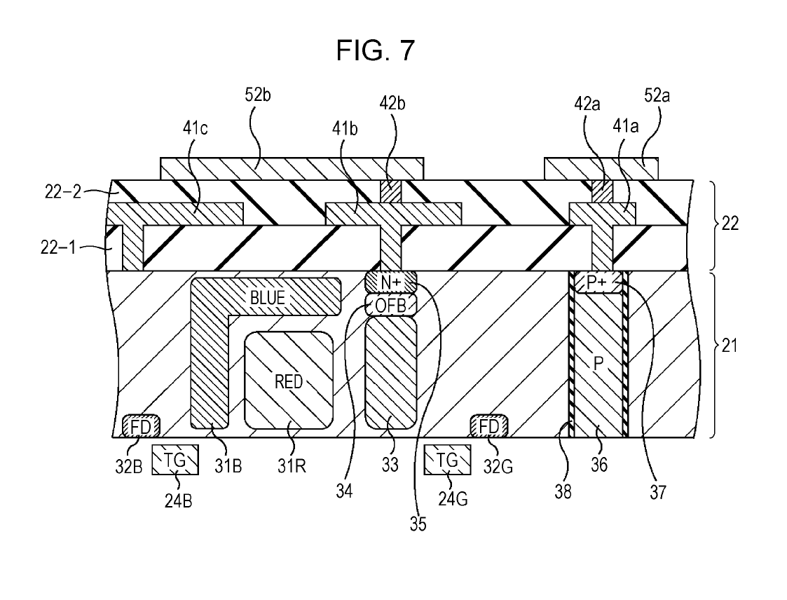

FIG. 7 illustrates a sixth step.

In the sixth step, lower electrodes 52a and 52b are formed on the insulating film 22-2. Since the lower electrode 52b is to transmit light, for example, the lower electrode 52b is formed by sputter-depositing an indium tin oxide (ITO) film, photolithographically patterning the ITO film, and dry- or wet-etching the patterned film. Examples of the materials that can be used to form the lower electrodes 52a and 52b include, in addition to ITO, tin oxide-based materials such as SnO₂ (containing a dopant), zinc oxide-based materials such as aluminum zinc oxide (ZnO doped with Al, e.g., AZO), gallium zinc oxide (ZnO doped with Ga, e.g., GZO), and indium zinc oxide (ZnO doped with In, e.g., IZO), CuI, InSbO₄, ZnMgO, CuInO₂, MgIN₂O₄, CdO, and ZnSnO₃.

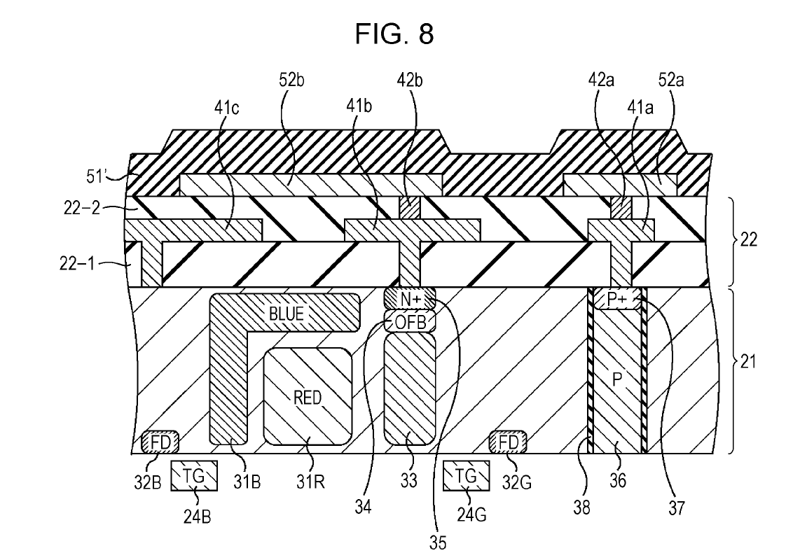

FIG. 8 shows a seventh step.

In the seventh step, an insulating film 51′ is formed on the lower electrodes 52a and 52b and the insulating film 22-2. The insulating film 51′ is constituted by, for example, a SiO₂ film formed by plasma-enhanced CVD.

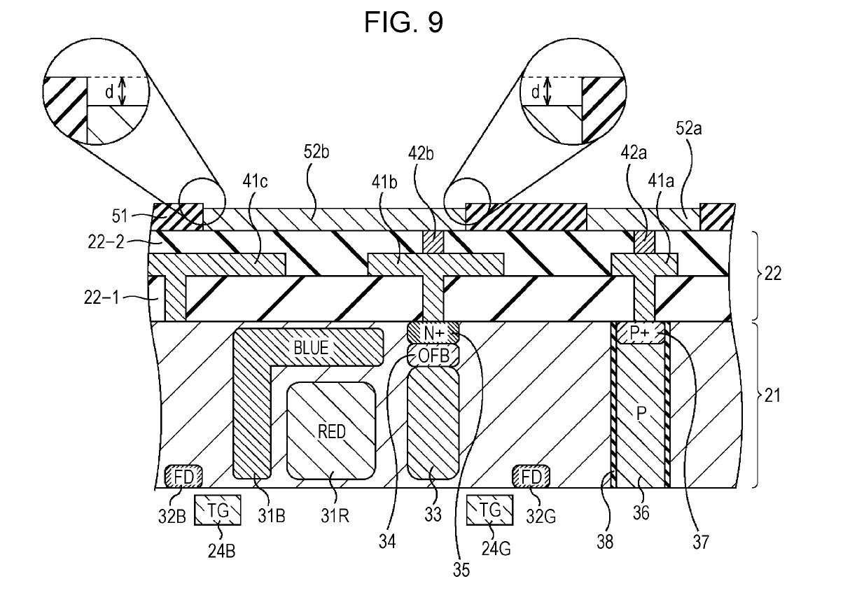

FIG. 9 illustrates an eighth step.

In the eighth step, the insulating film 51′ is planarized by, for example, CMP so as to form an insulating film 51 that exposes the lower electrodes 52a and 52b.

It is a common knowledge in the art that, when a planarizing technique such as CMP is used, dishing, erosion, and other problems typically arise and thus the upper surface of the lower electrode 52b and the upper surface of the insulating film 51 do not lie at the same height. For example, as illustrated in an enlarged portion of FIG. 9, the upper surface of the lower electrode 52b is lower than the upper surface of the insulating film 51, thereby forming a recessed structure. The depth d of the upper surface of the lower electrode 52b with respect to the upper surface of the insulating film 51 is preferably as small as possible. In particular, the depth d is 50 nm or less and preferably 20 nm or less. The structure may be any other structure as long as the upper surface of the lower electrode 52b does not protrude from the upper surface of the insulating film 51. For example, the upper surface of the lower electrode 52b and the upper surface of the insulating film 51 may lie at substantially the same height.

The conditions for CMP are as follows. The insulating film 51′ is polished with a commercially available oxide film CMP slurry until the lower electrodes 52a and 52b are exposed. The end point of polishing can be detected by the change in motor current of a polishing table the moment the lower electrodes 52a and 52b become exposed. Thus, the polishing can be ended at that point. For example, CMP is conducted by using a particular polishing pad at a pad rotation speed of 80 rpm, a polishing pressure of 4 psi, and a slurry flow rate of 150 ccm/min. As a result, a recessed structure in which the upper surface of the lower electrode 52b is lower than the upper surface of the insulating film 51 is obtained.

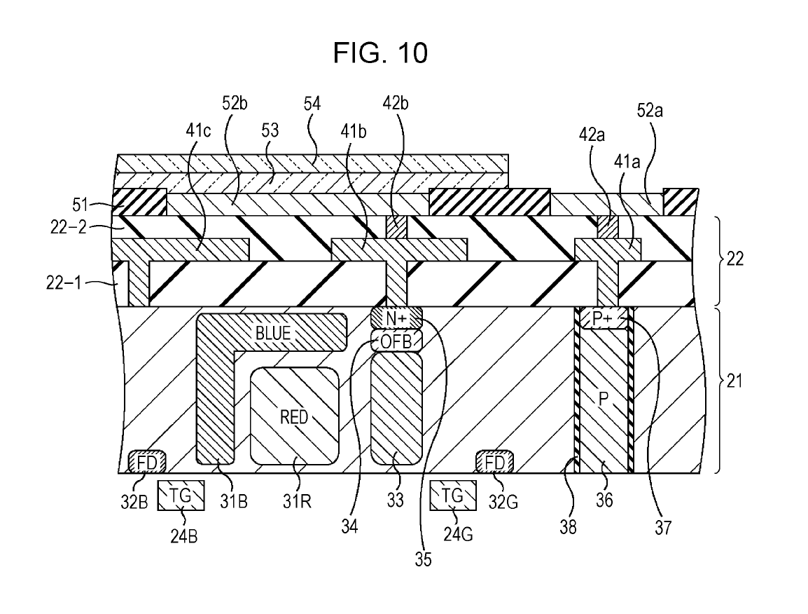

FIG. 10 illustrates a ninth step.

In the ninth step, an organic photoelectric conversion film 53 is formed on the lower electrode 52b and the insulating film 51 and an upper electrode 54 is formed on the organic photoelectric conversion film 53. In particular, the organic photoelectric conversion film 53 and the upper electrode 54 are formed by forming a film composed of a material for the organic photoelectric conversion film 53 on the entire surfaces of the lower electrodes 52a and 52b and the insulating film 51, forming a film composed of a material for the upper electrode 54 thereon, photolithographically patterning the films, and dry-etching the films. As a result, a structure in which the entire upper surface of the lower electrode 52b is in contact with the organic photoelectric conversion film 53 thereon and the side surfaces of the lower electrode 52b are covered with the insulating film 51 is formed.

The organic photoelectric conversion film 53 is formed by, for example, vacuum-vapor-depositing quinacridone. The organic photoelectric conversion film 53 may have a multilayered structure in which an undercoating film, an electron-blocking film, a photoelectric conversion film, a hole blocking film, a hole-blocking buffer film, and a work-function-adjusting film are stacked on a lower electrode, as described in Patent Document 3 described above.

The organic photoelectric conversion film 53 preferably contains at least one of an organic p-type semiconductor and an organic n-type semiconductor. Examples of the organic p-type semiconductor and the organic n-type semiconductor include quinacridone derivatives, naphthalene derivatives, anthracene derivatives, phenanthrene derivatives, tetracene derivatives, pyrene derivatives, perylene derivatives, and fluoranthene derivatives. Polymers such as phenylene vinylene, fluorene, carbazole, indole, pyrene, pyrrole, picoline, thiophene, acetylene and diacetylene, and derivatives thereof may also be used.

Other examples of the material for the organic photoelectric conversion film 53 include metal complex colorants, cyanine colorants, merocyanine colorants, phenylxanthene colorants, triphenylmethane colorants, rhodacyanine colorants, xanthene colorants, macrocyclic azaannulene colorants, azulene colorants, naphthoquinone, anthraquinone colorants, anthracene, fused polycyclic aromatic compounds such as pyrene, chain compounds obtained by fusing an aromatic ring compound or a heterocyclic compound, quinoline having a squarylium group and a croconic methine group as a bonding chain, nitrogen-containing heterocyclic compounds such as benzothiazole and benzoxazole, and cyanine-like colorants linked through a squarylium group and a croconic methine group. Preferred examples of the metal complex colorants include dithiol metal complex colorants, metallic phthalocyanine colorants, metallic porphyrin colorants, and ruthenium complex colorants. A ruthenium complex colorant is particularly preferable. However, the material is not limited to those described above.

The upper electrode 54 is to be transparent and formed by, for example, sputter-depositing ITO. The material of the upper electrode 54 may be ITO or any other material. Examples of the material include tin oxide-based materials such as SnO₂ (containing a dopant), zinc oxide-based materials such as aluminum zinc oxide (ZnO doped with Al, e.g., AZO), gallium zinc oxide (ZnO doped with Ga, e.g., GZO), and indium zinc oxide (ZnO doped with In, e.g., IZO), CuI, InSbO₄, ZnMgO, CuInO₂, MgIN₂O₄, CdO, and ZnSnO₃.

After the ninth step, as shown in FIG. 1, a contact metal layer 55 is formed so as to be connected to the lower electrode 52a and cover part of the upper surface of the upper electrode 54. The contact metal layer 55 may be composed of, for example, tungsten, titanium, titanium nitride, aluminum, or the like. Materials other than these may also be employed.

After the contact metal layer 55 is formed, a passivation film, a planarizing film, an on-chip lens, and other associated components not shown in the drawing are further formed.

According to the first method described above, a solid-state imaging device 11 having a recessed structure in which the upper surface of the lower electrode 52b is lower than the upper surface of the insulating film 51 can be formed.

The solid-state imaging device 11 is an example in which the photoelectric conversion unit 31B and the photoelectric conversion unit 31R are formed inside the semiconductor element substrate 21 and the organic photoelectric conversion film 53 is located above the semiconductor element substrate 21. However, any other configuration may be employed.

In the eighth step described with reference to FIG. 9, an example in which CMP is used to planarize the insulating film 51 is described. Alternatively, the insulating film 51 may be planarized by any other technique.

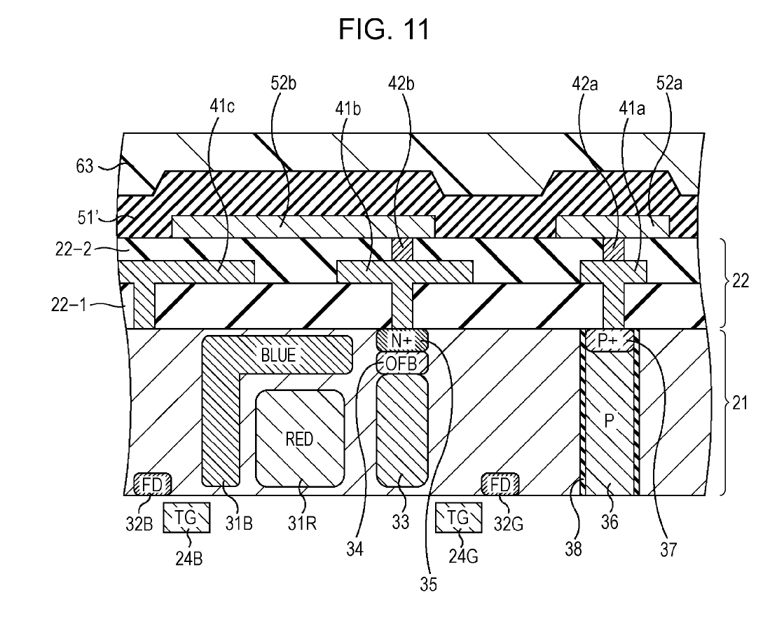

Examples of the other techniques for planarizing the insulating film 51 will now be described with reference to FIG. 11.

For example, after the insulating film 51′ is formed on the lower electrodes 52a and 52b and the insulating film 22-2 in the seventh step shown in FIG. 8, a resist 63 having a flat upper surface is formed as shown in FIG. 11. Then the resist 63 and the insulating film 51′ is etched back to form a recessed structure in which the upper surface of the lower electrode 52b is lower than the upper surface of the insulating film 51.

The conditions used for dry-etching the resist 63 and the insulating film 51′ are as follows. For example, the recessed structure mentioned above can be formed by using an parallel plate plasma etching apparatus by applying a frequency of 60 MHz to the upper electrode and 2 MHz to the lower electrode, using CF₄/O₂ gas at 100 mTorr, supplying 1000 W power to the upper electrode and 500 W power to the lower electrode, and adjusting the resist/oxide film selective ratio to about 1.

In some cases, the lower electrode 52b exposed by planarizing the insulating film 51 does not form a recessed structure shown in FIG. 9. In other words, the upper surface of the lower electrode 52b is in some cases not lower than the upper surface of the insulating film 51.

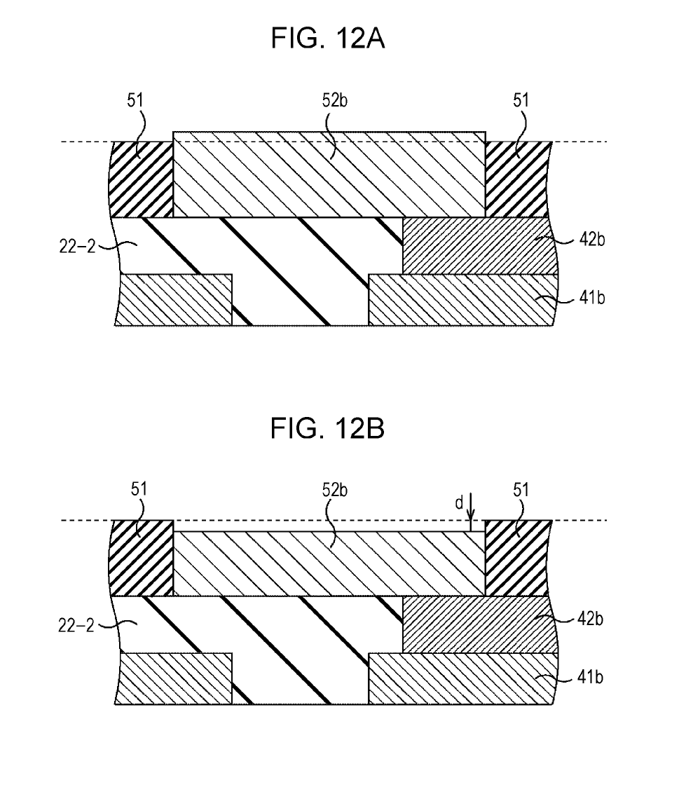

For example, as shown in FIG. 12A, when a protruding structure is formed, the lower electrode 52b is further wet- or dry-etched, for example, to form a recessed structure shown in FIG. 12B.

Examples of the process for wet-etching the lower electrode 52b include processes for removing the material for the lower electrode 52b by using a chemical solution such as a diluted hydrofluoric acid, hydrochloric acid, or oxalic acid. The lower electrode 52b may be dry-etched by using an inductively coupled plasma (ICP) or capacitively coupled plasma (CCP) etching apparatus with a Cl₂ 10 sccm/Ar 100 sccm gas at a plasma density of 10¹¹ atom/cm³ and a bias voltage of 300 V.

The process for etching the protruding lower electrode 52b may be applied in the first method described above and in a second method described below. The process of etching the protruding lower electrode 52b can be applied irrespective of whether CMP or dry-etching has been conducted in the planarization process.

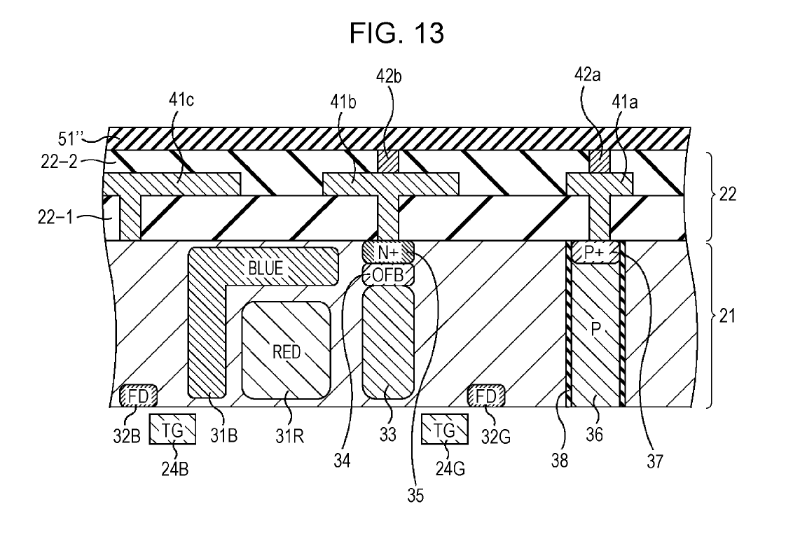

A second method for producing the solid-state imaging device 11 will now be described with reference to FIGS. 13 to 16.

First, the same steps as the first to fifth steps described with reference to FIGS. 2 to 6 are conducted to form a structure shown in FIG. 6. In other words, a structure is formed in which an interlayer insulating film 22 having conductive films 41a to 41c and conductive plugs 42a and 42b formed therein is stacked on a semiconductor element substrate 21 having the photoelectric conversion units 31B and 31R formed therein.

FIG. 13 shows a tenth step that follows the fifth step.

In the tenth step, for example, an insulating film 51″ constituted by a SiO₂ film formed by plasma-enhanced CVD or the like is formed on the entire surface of the interlayer insulating film 22.

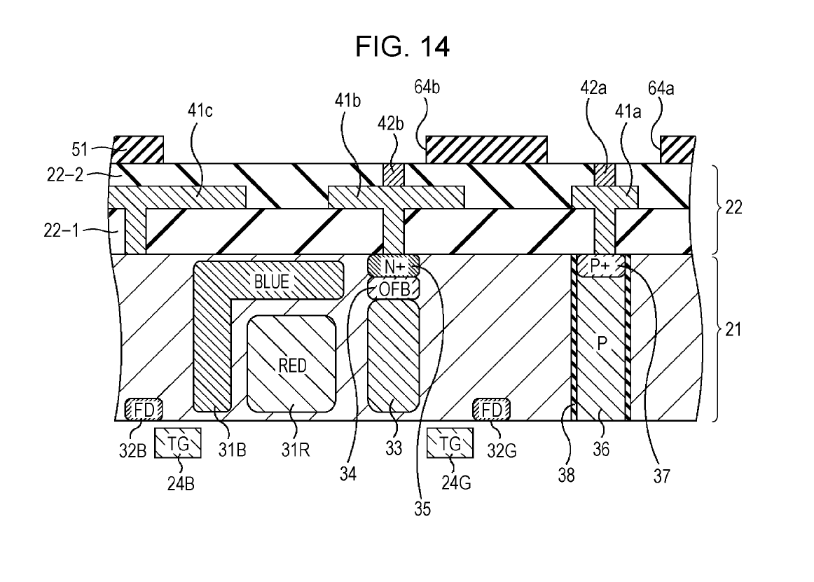

FIG. 14 illustrates an eleventh step.

In the eleventh step, trench openings 64a and 64b are formed in the insulating film 51″ at positions corresponding to the regions where lower electrodes 52a and 52b are to be formed. The trench openings 64a and 64b are formed by photolithography or dry etching. As a result, an insulating film 51 for insulating the lower electrodes 52a and 52b is formed.

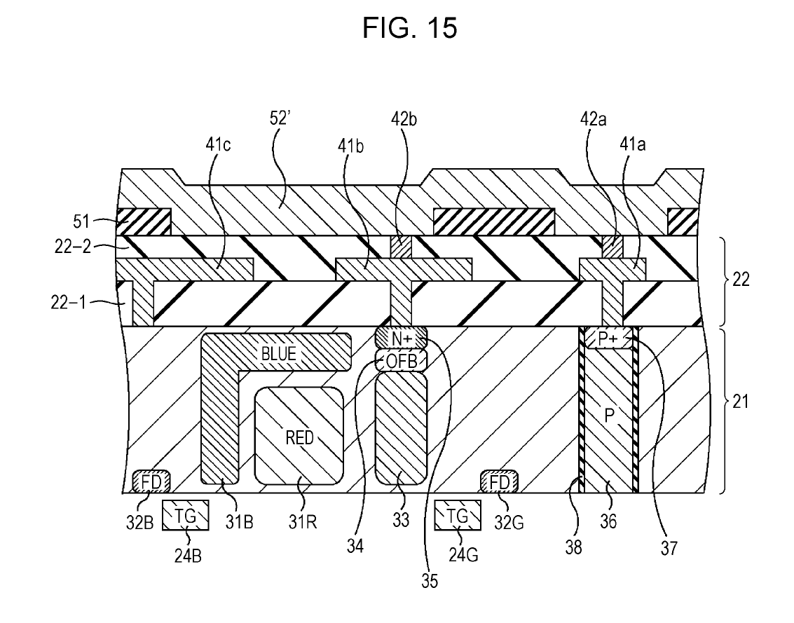

FIG. 15 illustrate a twelfth step.

In the twelfth step, a lower electrode film 52′, which is the material for forming the lower electrodes 52a and 52b, is formed on the entire surfaces of the interlayer insulating film 22 and the insulating film 51 by a sputtering method. The material for forming the lower electrode film 52′, i.e., the lower electrodes 52a and 52b, is the same as those described in the sixth step with reference to FIG. 7.

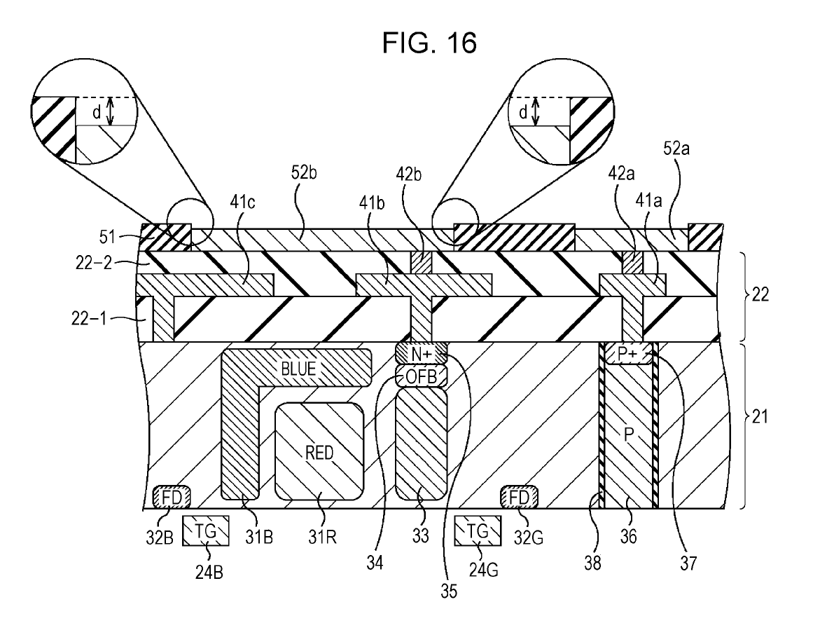

FIG. 16 shows a thirteenth step.

In the thirteenth step, for example, unneeded portions of the lower electrode film 52′ on the insulating film 51 are removed by CMP to form lower electrodes 52a and 52b.

As illustrated in an enlarged portion of FIG. 16, a recessed structure in which the upper surface of the lower electrode 52b is lower than the upper surface of the insulating film 51 is formed as with the first method. The depth d of the upper surface of the lower electrode 52b with respect to the upper surface of the insulating film 51 is preferably as small as possible. In particular, the depth d is preferably 50 nm or less and more preferably 20 nm or less. The structure may be any structure as long as the upper surface of the lower electrode 52b does not protrude from the upper surface of the insulating film 51. For example, the upper surface of the lower electrode 52b and the upper surface of the insulating film 51 may lie at substantially the same height.

The conditions for CMP are as follows. The lower electrode film 52′ is polished with a commercially available silica slurry containing an ITO etchant until the insulating film 51 is exposed in the lower electrode film 52′. The end point of polishing can be detected by the change in motor current of a polishing table the moment the insulating film 51 is exposed in the lower electrode film 52′. Thus, the polishing can be ended at that point. For example, CMP is conducted by using a particular polishing pad at a pad rotation speed of 80 rpm, a polishing pressure of 4 psi, and a slurry flow rate of 150 ccm/min. As a result, a recessed structure in which the upper surface of the lower electrode 52b is lower than the upper surface of the insulating film 51 is obtained.

Removal of the lower electrode film 52′ may be alternatively conducted by using an etch-back technique with an etching gas instead of CMP. The conditions for the dry etching are as follows. That is, an ICP or CCP etching apparatus is used with a Cl₂ 10 sccm/Ar 100 sccm gas at a plasma density of 10¹¹ atom/cm³ and a bias voltage of 300 V.

As with the first method, the second method can also be used to produce a solid-state imaging device 11 having a recessed structure in which the upper surface of the lower electrode 52b is lower than the upper surface of the insulating film 51.

As described in the eighth step (FIG. 9) and the thirteenth step (FIG. 16) above, when a planarizing technique such as CMP is used, dishing, erosion, and other problems arise and thus the upper surface of the lower electrode 52b and the upper surface of the insulating film 51 do not lie at the same height, resulting in formation of a recessed structure. In other words, the recessed structure created in the solid-state imaging device 11 may be a result of dishing, erosion, or the like that occurs during the planarizing process.

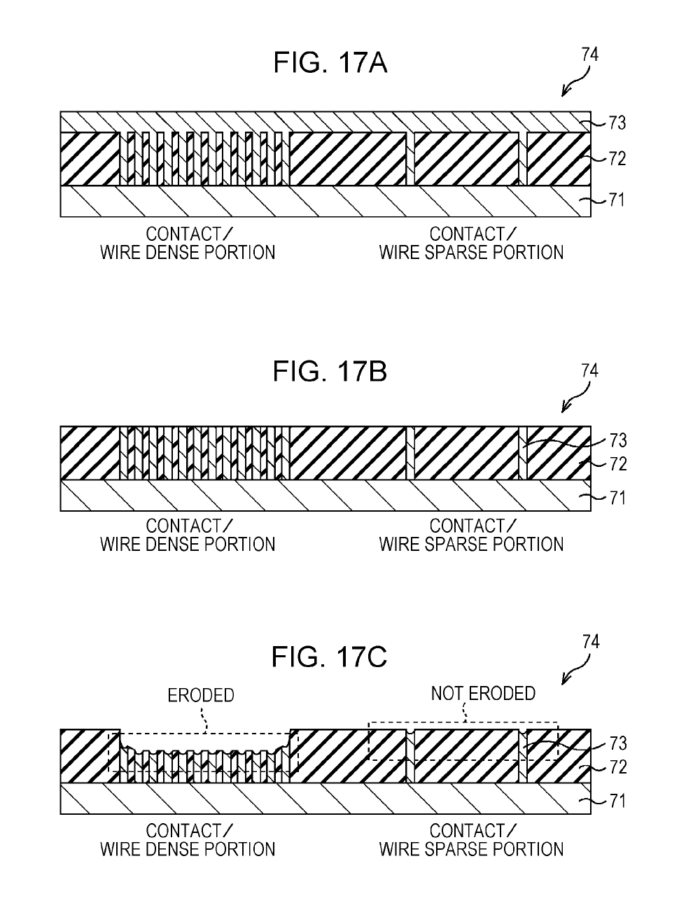

Erosion will now be described with reference to FIGS. 17A to 17C.

FIG. 17A shows a structure 74 formed by stacking an insulating film 72 on a substrate 71, forming contact holes in the insulating film 72, and filling the contact holes with a wire material 73. A dense portion in which contacts and wires are densely formed lies in the left half of FIG. 17A and a sparse portion in which contacts and wires are sparse lies in the right half of FIG. 17A.

When a planarizing technique such as CMP is employed on the structure 74 to expose the insulating film 72, the ideal result is the structure shown in FIG. 17B in which the upper surface of the insulating film 72 and the upper surface of the wire material 73 lie at the same height and are flat.

However, in actual planarization processes, as shown in FIG. 17C, a dense portion where the contacts and wires are densely provided become globally dented. This phenomenon is erosion in which the dense portion as a whole undergoes thickness reduction. In contrast, in a sparse portion where the contacts and wires are sparse, the upper surface of the wire material 73 may become lower than the upper surface of the insulating film 72 but a large dent (erosion) affecting the entire sparse portion does not occur.

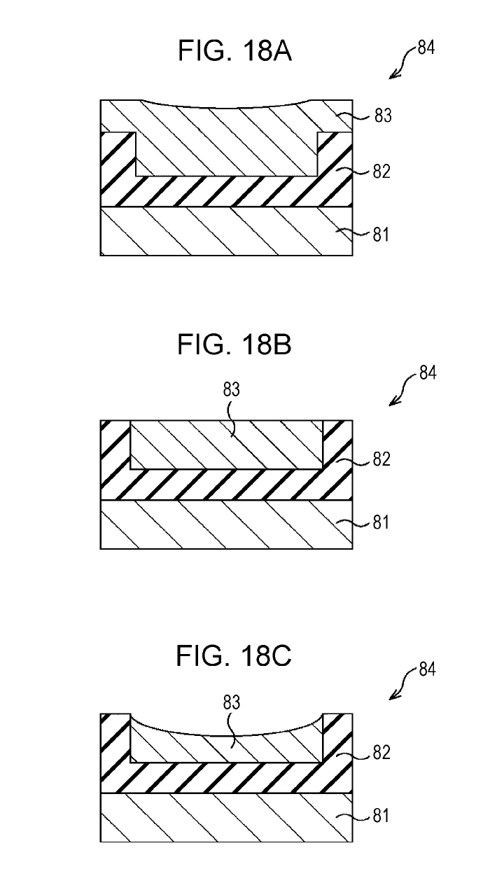

Next, dishing will be described with reference to FIGS. 18A to 18C. FIG. 18A shows a structure 84 formed by stacking an insulating film 82 on a substrate 81, forming a wide contact hole in the insulating film 82, and filling the wide contact hole with a wire material 83.

The structure 84 is planarized by a planarization technique such as CMP so as to expose the insulating film 82. The ideal result is the structure shown in FIG. 18B in which the upper surface of the insulating film 82 and the upper surface of the wire material 83 lie at the same height and are flat.

However, in actual planarization processes, a metal CMP slurry has a low polishing rate for insulating films and thus polishing of the wire material 83, which is a metal, proceeds alone. Thus, in the case where a wide wire is polished, thickness reduction (dishing) occurs as the wide wire is polished with a pad.

In the method for producing the solid-state imaging device 11, a recessed structure in which the upper surface of the lower electrode 52b is lower than the upper surface of the insulating film 51 may be a result of such erosion and dishing.

When such a recessed structure is formed, photoelectric conversion characteristics of the solid-state imaging device 11 can be improved.

According to the structure disclosed in Patent Document 4, electric field concentration occurred in edge portions of lower electrodes and deterioration of coverage of the photoelectric conversion film occurred in side wall portions. The same may occur in the technique described in Patent Document 3. In contrast, according to the solid-state imaging device 11, such electric field concentration and coverage deterioration can be suppressed, and thus, dark current in the photoelectric conversion device can be suppressed and voltage resistance deterioration can be controlled.

Patent Document 2 proposes a technique for reducing a gap between the lower electrodes by forming an insulating film. According to this technique, the insulating film is given a desired taper angle (preferably 30° or less) by forming the insulating film with a photosensitive material or by etching back a silicon oxide (SiO₂) film formed by CVD by using a resist mask having a tapered shape, and then an organic photoelectric conversion film is formed. However, according to this structure, the area of the openings of the lower electrodes is small, the contact area between the organic photoelectric conversion film and the lower electrodes is decreased, and the electron output efficiency is low. Forming the insulating film increases the height from the on-chip lens above to the silicon substrate. In order to improve the sensitivity of the photoelectric conversion unit in the silicon, the height from the on-chip-lens to the silicon substrate is preferably reduced.

In contrast, the solid-state imaging device 11 can maximize the contact area between the lower electrode 52b and the organic photoelectric conversion film 53 and can thus improve the output efficiency. Moreover, since the height from the on-chip-lens (not shown) to the semiconductor element substrate 21 can be reduced, the sensitivity can be improved.

The organic photoelectric conversion film 53 of the solid-state imaging device 11 may be replaced by a film composed of an inorganic material. Examples of the inorganic photoelectric conversion material include crystal silicon, amorphous silicon, copper indium gallium diselenide (CIGS), copper indium diselenide (CIS), chalcopyrite-structure semiconductors, and compound semiconductors such as GaAs.

In the case where a technique other than the vertical-type spectroscopic technique is employed, the lower electrode 52b may be a metal electrode instead of a transparent electrode. For example, when a material having a small work function is desirable, materials such as La, Er, Y, Yb, Zn, Ce, Sc, Pb, Mg, Mn, Al, Ag, Hf, Ta, Ti, Zr, and V, and a silicide, silicon nitride, or carbide film containing at least one of these materials may be employed. In contrast, when a material having a high work function is desirable, materials such as W, Ti, Ta, Cr, Ru, Rh, Co, Pb, Ni, Re, Ir, Pr, Mo, and Au and a silicide, silicon nitride, or carbide film containing at least one of these materials may be employed.

Although the solid-state imaging device 11 has one organic photoelectric conversion film 53, two organic photoelectric conversion films 53 may be provided and one photoelectric conversion unit 31 may be formed inside the semiconductor element substrate 21.

The solid-state imaging device 11 described above can be applied to various types of electronic appliances such as imaging systems such as digital still cameras and digital video cameras, cellular phones having imaging functions, and other devices having imaging functions.

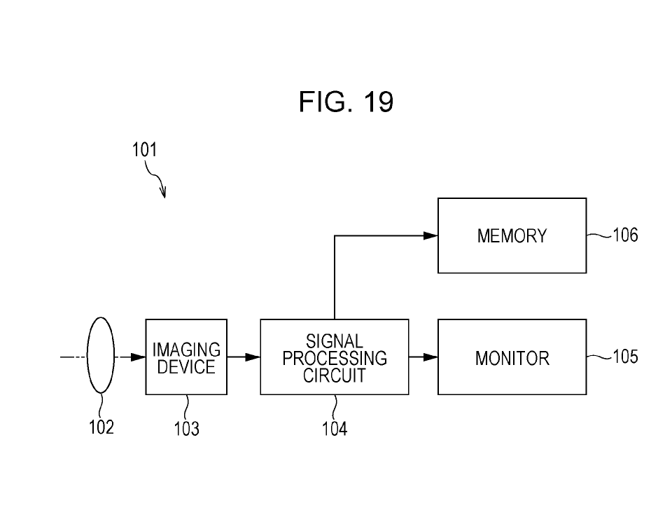

FIG. 19 is a block diagram illustrating an example configuration of an imaging system mounted in an electronic apparatus.

As shown in FIG. 19, an imaging system 101 includes an optical system 102, an imaging device 103, a signal processing circuit 104, a monitor 105, and a memory 106 and can take a still image or a moving image.

The optical system 102 is constituted by one or more lenses, guides image light (incoming light) from a subject to the imaging device 103, and causes an image to form on a light-receiving surface (sensor portion) of the imaging device 103.

A solid-state imaging device 11 having any of the example configurations described above is used as the imaging device 103. Electrons are stored in the imaging device 103 for a particular period of time in response to the image formed on the light-receiving surface via the optical system 102. Then signals corresponding to the electrons stored in the imaging device 103 are supplied to the signal processing circuit 104.

The signal processing circuit 104 conducts various types of signal processing on signal charges output from the imaging device 103. An image (image data) obtained by signal processing in the signal processing circuit 104 is supplied to and displayed in the monitor 105 or fed to and stored (recorded) in the memory 106.

The imaging system 101 having this configuration and including the solid-state imaging device 11 as the imaging device 103 can achieve improved image quality.

The solid-state imaging device 11 may be applied to a front-illuminated CMOS solid-state imaging device or a CCD solid-state imaging device instead of a back-illuminated CMOS solid-state imaging device.

The technique disclosed herein may take following configurations.

(1)

A solid-state imaging device including:

a semiconductor substrate; and

a photoelectric conversion layer above the semiconductor substrate, the photoelectric conversion layer including
a lower electrode having a side surface insulated with an insulating film;
a photoelectric conversion film on the lower electrode; and
an upper electrode, the upper electrode and the lower electrode sandwiching the photoelectric conversion film,

in which an upper surface of the lower electrode is lower than an upper surface of the insulating film.

(2)

The solid-state imaging device according to (1), in which the upper surface of the lower electrode is entirely in contact with the photoelectric conversion film and the side surface of the lower electrode is entirely covered with the insulating film.

(3)

The solid-state imaging device according to (1) or (2), in which the lower electrode and the upper electrode are optically transparent and formed of indium tin oxide, tin oxide, a zinc-oxide material, CuI, InSbO₄, ZnMgO, CuInO₂, MgIN₂O₄, CdO, or ZnSnO₃.

Embodiments are not limited those described above and various modifications are possible without departing from the scope of the present disclosure.

The present disclosure contains subject matter related to that disclosed in Japanese Priority Patent Application JP 2011-158051 filed in the Japan Patent Office on Jul. 19, 2011, the entire contents of which are hereby incorporated by reference.

What is claimed is:

1. A solid-state imaging device comprising:
a semiconductor substrate; and
a photoelectric conversion layer above the semiconductor substrate, the photoelectric conversion layer including
a lower electrode having a side surface insulated with an insulating film;
a photoelectric conversion film on the lower electrode; and
an upper electrode, the upper electrode and the lower electrode sandwiching the photoelectric conversion film,
wherein an upper surface of the lower electrode is lower than an upper surface of the insulating film.

2. The solid-state imaging device according to claim 1, wherein the upper surface of the lower electrode is entirely in contact with the photoelectric conversion film and the side surface of the lower electrode is entirely covered with the insulating film.

3. The solid-state imaging device according to claim 1, wherein the lower electrode and the upper electrode are optically transparent and are each formed of indium tin oxide, tin oxide, a zinc oxide-based material, CuI, InSbO₄, ZnMgO, CuInO₂, MgIN₂O₄, CdO, or ZnSnO₃.

4. A method for producing a solid-state imaging device that includes a semiconductor substrate and a photoelectric conversion layer above the semiconductor substrate, the method comprising:
forming an interlayer insulating film on the semiconductor substrate;
forming a lower electrode on the interlayer insulating film;
forming an insulating film on the interlayer insulating film and the lower electrode and planarizing the insulating film so as to expose the lower electrode;
forming a photoelectric conversion film on the lower electrode; and
forming an upper electrode so as to sandwich the photoelectric conversion film between the upper electrode and the lower electrode,
wherein, in planarizing the insulating film, an upper surface of the lower electrode is formed to be lower than an upper surface of the insulating film.

5. A method for producing a solid-state imaging device that includes a semiconductor substrate and a photoelectric conversion layer above the semiconductor substrate, the method comprising:
forming an interlayer insulating film on the semiconductor substrate;
forming an insulating film on the interlayer insulating film, the insulating film having an opening in a region where a lower electrode is to be formed;
forming an electrode film, which is to form the lower electrode, on the interlayer insulating film and the insulating film and planarizing the electrode film so as to expose the insulating film and to thereby form the lower electrode;
forming a photoelectric conversion film on the lower electrode; and
forming an upper electrode so that the photoelectric conversion film is sandwiched between the lower electrode and the upper electrode,
wherein, in planarizing the insulating film, an upper surface of the lower electrode is formed to be lower than an upper surface of the insulating film.

6. An electronic apparatus comprising:
a solid-state imaging device that includes a semiconductor substrate and a photoelectric conversion layer above the semiconductor substrate, the photoelectric conversion layer including
a lower electrode having a side surface insulated with an insulating film;
a photoelectric conversion film on the lower electrode; and
an upper electrode, the upper electrode and the lower electrode sandwiching the photoelectric conversion film,
wherein an upper surface of the lower electrode is lower than an upper surface of the insulating film.
